(19) United States
(12) Patent Application Publication
(10) Pub. No.: US 2016/0238679 A1
(43) Pub. Date: Aug. 18, 2016

(54) RF PROBE FOR MAGNETIC RESONANCE IMAGING AND SPECTROSCOPY

(71) Applicant: Technical University of Denmark, Lyngby (DK)

(72) Inventor: Vitaliy Zhurbenko, Virum (DK)

(21) Appl. No.: 15/141,257

(22) Filed: Apr. 28, 2016

Related U.S. Application Data
(63) Continuation of application No. PCT/EP2014/073085, filed on Oct. 28, 2014.

(30) Foreign Application Priority Data
Oct. 28, 2013 (EP) 13190433.6

(51) Int. Cl. G01R 33/34; G01R 33/345

(52) U.S. Cl. CPC G01R 33/34076; G01R 33/345

(57) ABSTRACT

The present disclosure relates to a probe for use within the field of nuclear magnetic resonance, such as magnetic resonance imaging (MRI), and magnetic resonance spectroscopy (MRS)). One embodiment relates to an RF probe for magnetic resonance imaging and/or spectroscopy comprising a conductive non-magnetic hollow waveguide having an internal volume and at least one open end, one or more capacitors and at least a first conductive non-magnetic wire, wherein said first conductive wire connects at least one of said one or more capacitors to opposite walls of one open end of the waveguide and wherein said first conductive wire and said one or more capacitors are located outside of said internal volume, wherein the internal volume of the hollow waveguide defines an imaging volume or sample volume.

### CROSS-REFERENCE TO RELATED APPLICATIONS

The present application is a continuation of PCT/EP2014/073085 filed Oct. 28, 2014, which claims priority of European Patent Application 13190433.6 filed Oct. 28 2013, the entire contents of which are incorporated herein by reference.

### FIELD OF THE INVENTION

The present disclosure relates to an RF probe for use within the field of nuclear magnetic resonance, such as magnetic resonance imaging (MRI) and magnetic resonance spectroscopy (MRS).

### BACKGROUND OF INVENTION

The human or animal body is largely composed of water molecules which each contain two hydrogen nuclei or protons. When a person goes inside the powerful static magnetic field of an MR scanner, the magnetic moments of these protons align with the direction of the field. A radio frequency (RF) electromagnetic field is then briefly turned on, causing the protons to alter their magnetization alignment relative to the static field. When the RF field is turned off the protons return to the original magnetization alignment. These magnetization alignment changes create a signal which can be detected by the MR scanner. However, MRI is not limited to imaging of hydrogen nuclei. It is also used for imaging carbon, phosphorus, and other nuclei, e.g. in MRS.

The magnetic resonance frequency of the protons depends on the strength of the applied static magnetic field. The position of protons in the body can be determined by applying additional gradient magnetic fields during the scan which allows an image of the scanned subject to be created. These additional magnetic fields are provided by gradient coils. Subatomic particles have the quantum mechanical property of spin. When these spins are placed in a strong external magnetic field they precess around an axis along the direction of the static field. In the static magnetic fields commonly used in MRI, the energy difference between the nuclear spin states corresponds to a radio frequency photon. Resonant absorption of energy by the protons due to an external oscillating magnetic field will occur at the Larmor frequency for the particular nucleus.

A radio frequency transmitter can create the magnetic field which rotates the net magnetization using a pulse sequence. When the radio frequency pulse is turned off, the transverse vector component produces an oscillating magnetic field generating an RF signal. This can induce a small current in a radio frequency (RF) probe, such as an RF receiver coil. An RF receiver can therefore detect the transverse magnetization as it precesses in the XY plane in the scanner, thereby detecting RF electromagnetic radiation produced by the nuclear relaxation inside the scanned subject.

The RF transmitter and RF receiver probes may be one and the same device which serves as the transmitter of the magnetic fields and receiver of RF energy from the imaged object. Traditionally, these RF transmitting and receiving probes are referred to as RF coils, because they are typically formed as coils or comprise coils. There are various types of RF coils, e.g. volume coils that are configured to surround the imaged object while surface coils are configured to be placed adjacent to the imaged object. Examples of volume coils are birdcage coils (pictured in FIGS. 2a and 2b), saddle coils, and Alderman-Grant coils.

An RF coil must resonate, or efficiently store energy, at the Larmor frequency and is therefore typically composed of an inductor, or inductive elements, and a set of capacitive elements. The resonant frequency of an RF coil is determined by the equivalent inductance (L) and capacitance (C) of the circuit.

U.S. Pat. No. 5,107,217 shows an example of a radio frequency antenna for nuclear magnetic resonance tomography apparatus having interior conductors which form a transmission line resonator. A hollow cylindrical waveguide (sheet 2 in FIG. 1) may consist of copper. This waveguide surrounds the interior conductors and shortening capacitors. It can be noted that the interior conductors are disposed at spaced positions around the surface, and as a consequence the currents do not distribute themselves uniformly but typically concentrated in the regions of the gaps.

GB 2,159,958 contains an example of prior art embodied in the form of an RF field generating and detecting arrangement (FIG. 1, for the purpose of showing prior art to the invention disclosed in GB 2,159,958) This example does not have a closed surface waveguide but rather four separate arcuate sheets, which are also disposed at spaced positions, hence having the same disadvantage that the currents do not distribute themselves uniformly but typically concentrated in the regions of the gaps. In GB 2,159,958 this is said to be improved by introducing additional members in the gap between the sheets acting as parasitic elements and reduce concentration of currents in the regions of the gaps.

### SUMMARY OF INVENTION

One health issue within MRI is due to the powerful RF transmitter necessary for generating the RF field for exciting the protons. If the body absorbs the energy, heating occurs. This is quantified as specific absorption rate (SAR). Other issues within magnetic resonance are the eternal quest for improving the resulting image quality and the complexity and fabrication costs of the probe.

One embodiment of the present disclosure relates to an RF probe for magnetic resonance imaging and/or spectroscopy comprising a conductive non-magnetic hollow waveguide having an internal volume and at least one open end, one or more capacitors and at least a first conductive non-magnetic wire, wherein said first conductive wire connects at least one of said one or more capacitors to opposite walls of one open end of the waveguide and wherein said first conductive wire and said one or more capacitors are located outside of said internal volume, wherein the internal volume of the hollow waveguide defines an imaging volume or sample volume. This internal volume of the hollow waveguide preferably defines an imaging volume, e.g. in case of MRI, and/or sample volume, e.g. in case of MRS. Waveguide in the scope of the present invention can be understood as a hollow non-magnetic, conducting pipe or tube and is described in greater detail below.

The RF probe as disclosed herein is thus suitable as RF transmitting and/or RF receiving probe for use in MRI and/or MRS and preferably configured to surround at least a part of the subject of interest. Alternatively, the RF probe could be referred to as a volume probe for magnetic resonance imaging and/or spectroscopy.

There are several inductive components which are capable of storing energy in a magnetic field. These components can be used to generate a magnetic field in RF probes for MRI. One of such components is a conductive non-magnetic hollow waveguide. Such a waveguide has an intrinsic cutoff frequency. Below this cutoff frequency the waveguide can exhibit inductive behavior and concentrate magnetic field inside its interior. This field can then be used to excite a sample or subject in MR. One or more capacitors can be connected to the waveguide such that the structure resonates at a certain predefined frequency of operation—the Larmor frequency—and thereby provide an RF probe suitable for use in MRI. The configuration of the waveguide and the connected capacitor(s) can be selected such that the resonance frequency of the RF probe is below the cutoff frequency of the waveguide.

The presently disclosed RF probe can potentially reduce health risks associated with high field MRI because the SAR is smaller, MR image quality can be improved due to the possibility of increased homogeneity of the magnetic field, and fabrication and operation costs can be reduced due to reduced complexity of the design in comparison to the traditional probes (e.g. RF coils).

The herein disclosed RF probe is thus preferably suitable for magnetic resonance imaging and/or for magnetic resonance spectroscopy.

### DESCRIPTION OF DRAWINGS

The invention will now be described in further detail with reference to the drawings in which

FIG. 1 is an illustration of a traditional RF coil in the form of a birdcage probe.

FIG. 2a is an illustration of birdcage coil with phantom subject inside.

FIG. 2b is a photo of a MRI birdcage coils.

FIG. 3a is an illustration of cylindrical hollow waveguide.

FIG. 3b is a photo of a hollow copper waveguide.

FIGS. 3c-d show photos of traditional waveguide applications within MR.

FIGS. 4a-f illustrate some of the principles of the presently disclosed RF probe.

FIG. 5a is a schematic illustration of one embodiment of an RF probe as herein described.

FIGS. 5b-c are photos of two prototypes of the presently disclosed RF probe.

FIG. 5d shows a comparison of measured and predicted response of the prototype probes.

FIG. 6a illustrates the computed SAR distribution for a birdcage coil.

FIG. 6b illustrates the computed SAR distribution for one embodiment of the presently disclosed RF probe.

FIG. 7 illustrates the amplitudes of the magnetic field along z-axis for a birdcage coil and one embodiment of the present RF probe.

FIG. 8 illustrates a plurality of the presently disclosed RF probes connected in series.

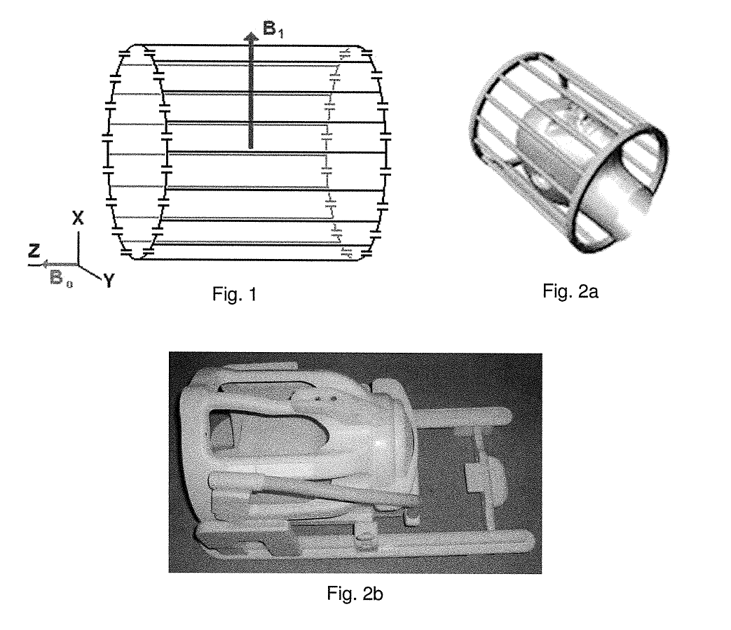

### BACKGROUND ON WAVEGUIDES FOR RF SHIELDING

MRI scanners require RF shielding nearly 100% of the time. RF shielding must create a complete box with all walls, ceiling, and flooring covered with an RF shield. The RF shield can be made of almost any metal, but the most common types of metals are copper, galvanized steel and aluminum. The RF shield thereby keeps out spurious signals both from foreign transmitters and from the driving electronics of the MRI system itself. As an example, the typical performance required of an MRI shield is to achieve 100 dB of RF signal attenuation at 100 MHz. The RF shield forms a complete box around the MRI system and the RF shield thereby forms a Faraday cage: a closed conductive structure, i.e. an electrically continuous envelope of conductive material that is connected to ground. Everything that is to come into the MRI room must pass through an RF filter or waveguide. RF filters are mounted on the RF shield and create a penetration point for electrical power for lighting or powered outlets within the MRI room. RF filters also accommodate data cables.

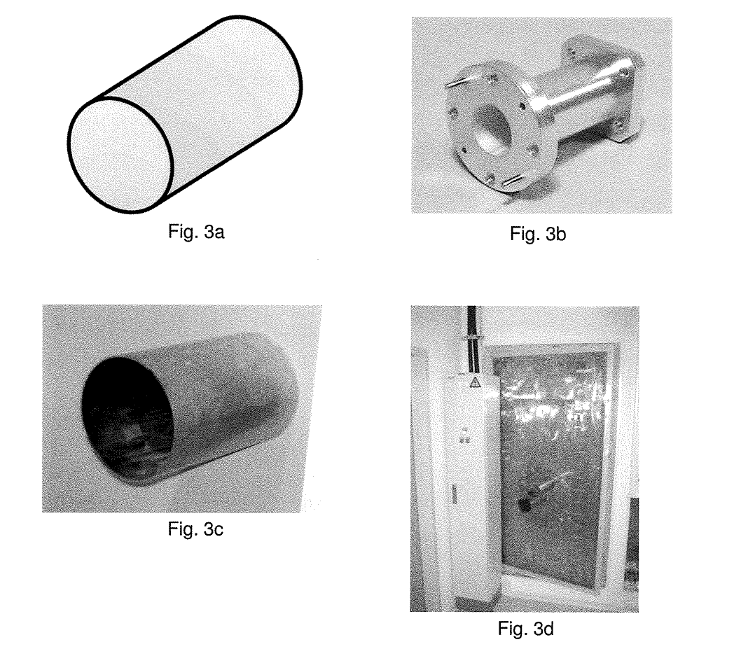

In the field of MRI RF shielding waveguides are used as penetrations in the RF shield that allow the passage of non-electric elements into the MRI room without compromising the shielding effectiveness. Water, gas or air all provide a fluid flow, which is non-current-carrying, and thus require a waveguide. Waveguides are typically conductive tubes that attenuate any RF noise entering the tube. The diameter of the waveguide determines the cutoff frequency, i.e. any frequency below the cutoff frequency will be attenuated. Waveguides come in a variety of shapes and sizes depending on the application. A dielectric (such as air) is typically included in the construction of the waveguide in order to maintain electrical isolation between the shielded enclosure and the outside environment. Pictures of copper waveguides in RF shielding for MRI are shown in FIGS. 3c and 3d. FIG. 3c is a close-up picture of a copper waveguide and FIG. 3d shows a copper door with two copper waveguides extending there through as part of an RF shield in an MRI system, i.e. the waveguides penetrate the RF shield constituted by the copper wall.

### DETAILED DESCRIPTION OF THE INVENTION

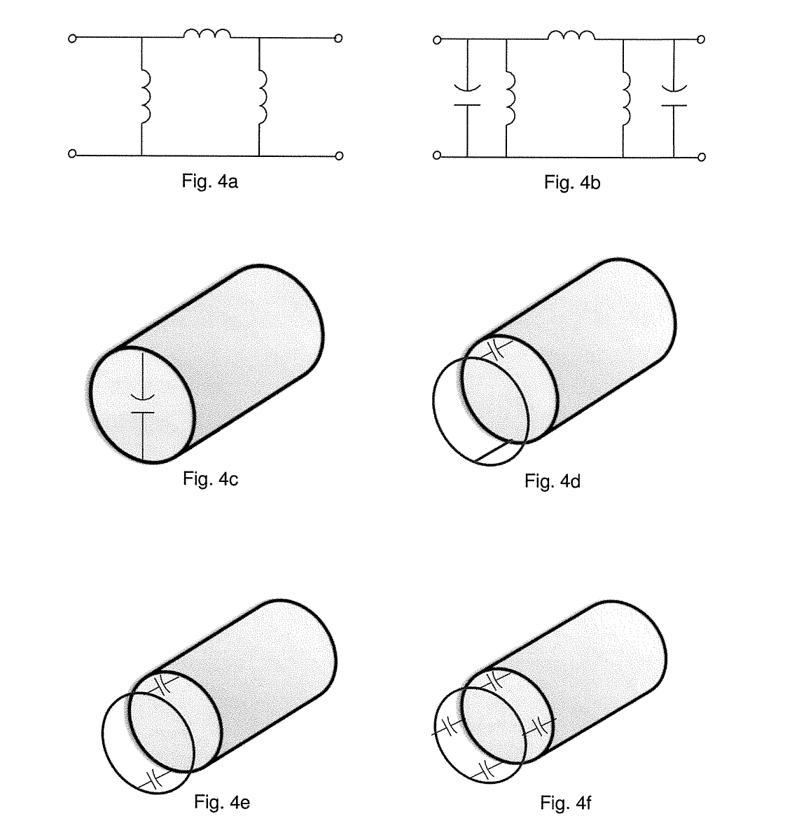

In the present disclosure a waveguide is applied in an RF probe for MR. The purpose of an MRI probe is to generate (or sense) a certain magnetic field distribution in a subject or sample. There are several inductive components which are capable of storing energy in a magnetic field. These components can be used to generate a magnetic field in MRI probes. One of such components is a piece of a circular or rectangular metallic waveguide as illustrated in FIG. 3a operating below its cutoff frequency. The behavior of such a waveguide can be described with a combination of inductors as it is shown in FIG. 4a. The diameter and length of the waveguide in FIG. 3a define the values of the inductors in the circuit in FIG. 4a. One or two (for symmetry) capacitors can be added to this circuit as illustrated in FIG. 4b in order to support electromagnetic wave propagation. The circuit now represents two inductively coupled resonators. This structure (FIG. 4b) now becomes resonant considerably increasing the amplitude of the currents, and, consequently, magnetic field in the inductive elements. The waveguide version of the circuit in FIG. 4b is illustrated in FIG. 4c where capacitors are inserted in the two open ends of the waveguide. According to the equivalent circuit in FIG. 4b, there are two capacitors—at each end of the waveguide section. However, only one capacitor is visible in FIG. 4c because only one open end of the waveguide is visible. Such structures are used in communications as a building block for radiofrequency filters.

Using this waveguide as an RF probe for MR requires that the capacitive elements are moved outside the waveguide, and that at least one end of the waveguide is open. Such an opening of the waveguide will typically not result in radiation loss because the waveguide is operating below its cutoff frequency. The opening can be used to place the capacitive elements out of the volume of the waveguide. The resulting structure is shown in FIG. 4d where a conductive wire is connecting the capacitor to opposite walls of one end of the waveguide. The internal volume of the waveguide is now free from any circuit elements. Thus, a sample can now be placed inside the waveguide.

The capacitor can alternatively be substituted by two series connected capacitors (e.g. with doubled value) creating the symmetry in the structure and contributing to the homogeneity of generated fields. This is illustrated in FIG. 4e. In this structure the waveguide can exhibit inductive behavior and can concentrate magnetic field inside its internal volume. This field can then be used to excite a sample or subject in MR. The capacitors are chosen such that the structure resonates at a certain frequency of operation below the cutoff frequency of the waveguide. The field distribution in the waveguide resembles the field distribution for the fundamental mode in a waveguide having mainly linear orientation. Circularly rotating magnetic field would typically provide better efficiency in MR. Circular rotation of the field can be achieved by combining to linear fields shifted by 90 deg. in time and space. To support that, two more capacitors on each side of the waveguide can be added as illustrated in FIG. 4f.

As stated previously, the capacitive element(s) are selected such that the resonance frequency of the RF probe is below the cutoff frequency of the hollow waveguide. Below cutoff hollow waveguides are e.g. known from microwave filters where circuit elements (capacitors, inductors, or both) are inserted inside the hollow waveguide. With components inside the internal volume of the waveguide the use of such structures as MR probes is prevented since the internal volume of the probe is adapted for the subject or sample that is to be examined. Within the field of magnetic resonance there is usually no room for the circuit elements inside the internal volume of MR probes. In the presently disclosed RF probe the components that allows for below cutoff operation have been located outside of the internal volume of the hollow waveguide such that there is room for (at least a part of) a subject or a sample inside this internal volume.

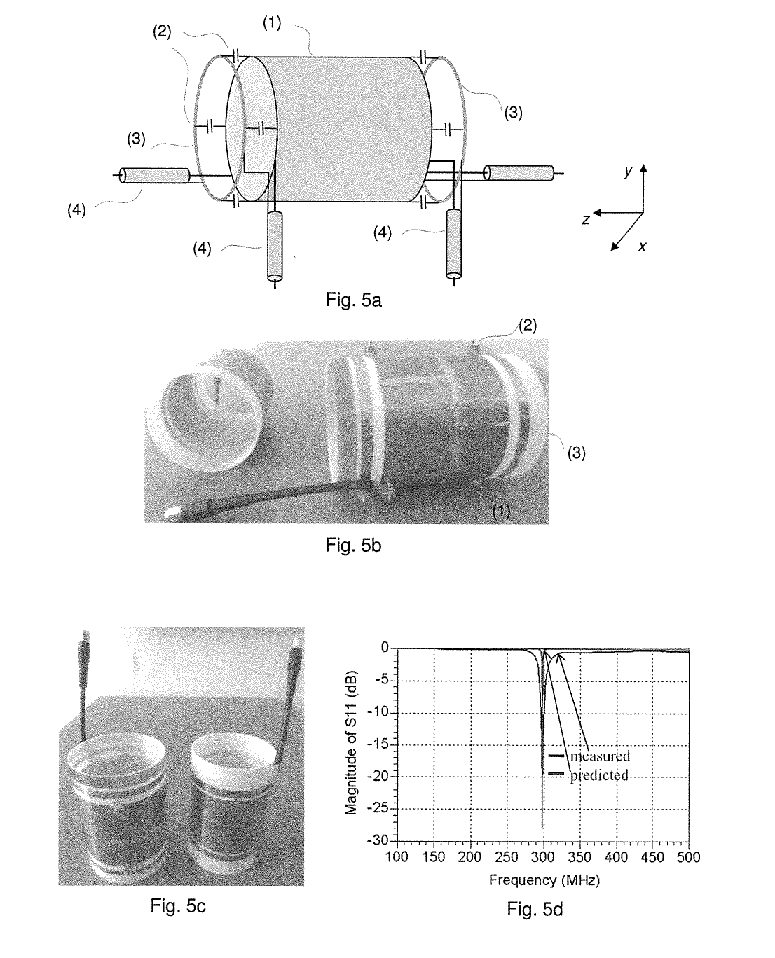

As stated, a waveguide in the scope of the present invention can be understood as a hollow non-magnetic conducting pipe or tube and the intended functionality of the waveguide is to provide below cut-off operation together with appropriate selected capacitors. There are several possible shapes of the waveguide to obtain the desired functionality, e.g. in the form of a pipe. Further, the side surface of the waveguide/pipe, i.e. the side surface that extends in the axial extension of the waveguide/pipe, is preferably one closed surface. This means that it shapes an internal closed volume inside the waveguide/pipe. However, the ends of the waveguide/pipe may be open; the waveguide of the presently disclosed RF probe has at least one open end. An example of a pipe is a hollow cylinder. This example can be seen in FIG. 5a. In this example the side surface is parallel to the axial extension of the pipe (z-axis in FIG. 5a).

In FIGS. 5b-c the waveguide is formed from a solid copper plate. But the desired functionality of the waveguide can also be achieved if the surface of the waveguide is at least partly or completely meshed, e.g. like a cage. The size of the holes in the mesh is preferably selected to be below 1/20 of the wavelength in order not to disturb the currents on the surface of the waveguide.

With a pipe/tube design with the side surface that extends in the axial extension of the pipe being a closed surface, or a surface being partly or completely meshed as described, the desired below cut-off operation can be achieved and a homogenous generated field can be generated with the appropriate selection of capacitors, which can be used to excite a sample or subject in MR.

The principle of the presently disclosed RF probe is illustrated in FIGS. 4d, 4e and 4f with a circular hollow (cylindrical) waveguide wherein the conductive wire in the form of a conductive ring is located in extension of the waveguide and one, two or four capacitors are connected between an open end of the waveguide and the conductive ring. The principle of the presently disclosed RF probe may therefore be seen as a section of a below cutoff waveguide with parallel connected capacitive susceptances.

In one embodiment the hollow waveguide comprises two open ends. Symmetric RF probes with two open ends may improve the homogeneity of the applied RF field.

In a further embodiment at least two capacitors are provided wherein said first conductive wire connects two of said capacitors to opposite walls of one open end of the waveguide. An example of this is illustrated in FIG. 4e. In a further embodiment at least four capacitors are provided, wherein said first conductive wire connects four of said capacitors to one open end of the waveguide, said four capacitor connections preferably distributed evenly around the rim of said open end of the waveguide. An example of this is illustrated in FIG. 4f.

In yet a further embodiment at least two capacitors and at least a second conductive non-magnetic wire are provided, wherein the second wire connects at least one of said capacitors to opposite walls of the opposite end of the waveguide. A more homogeneous field may be provided if one or more capacitors are provided at both ends of a linear waveguide. Thus, at least four capacitors may be provided wherein said second conductive wire connects two of said capacitors to opposite walls of the opposite end of the waveguide. And likewise at least eight capacitors may be provided, wherein said second conductive wire connects four of said capacitors to the opposite end of the waveguide, said four capacitor connections preferably distributed evenly around the rim of said opposite end of the waveguide.

The conductive wire and the capacitive elements are located outside of the internal volume of the waveguide. Thus, the first and/or the second conductive non-magnetic wire may be placed in axial extension of the waveguide. E.g. as illustrated in FIGS. 4d-f and FIGS. 5a-c, where the conductive wire is one or more rings located in axial extension of the hollow waveguide. The first and/or second conductive non-magnetic wire may form a closed loop. E.g. the first and/or second conductive non-magnetic wire forms an elliptical ring, such as a circular ring.

In one embodiment of the present disclosure the hollow waveguide is straight and/or elongated, e.g. cylindrical as illustrated in FIGS. 4 and 5. The hollow waveguide may take almost any shape as long as an internal volume is created inside the waveguide. Thus, the hollow waveguide may e.g. be rectangular.

Likewise the cross-section of the hollow waveguide may take any shape, however preferably the cross-section is convex. Thus, the cross-section may be elliptical, such as circular. The cross-section of the hollow waveguide may form a polygon, preferably an equilateral and/or convex polygon, a polygon such as a triangle, square, pentagon, hexagon, heptagon, etc.

In one embodiment of the present disclosure the hollow waveguide and/or the first and second conductive wires are manufactured in a non-magnetic metal, such as copper, aluminium, or steel.

In one embodiment of the present disclosure the hollow waveguide and/or the conductive wire(s) is a self-supporting structure. E.g. is manufactured in copper, the material is strong enough to be self-supporting. However, it may be advantageous to provide the waveguide with a thin surface. Thus, the waveguide and/or the first and second conductive wires may be mounted on a dielectric support structure, e.g. as illustrated in FIG. 5b and FIG. 5c, where thin copper waveguides and rings are mounted on a plastic cylinder to form a hollow conductive waveguide.

In order to excite (or sense) the field in the presently disclosed RF probe standard excitation schemes can be used. E.g. magnetic loops positioned perpendicular to the magnetic field vector, or monopoles parallel to the electric field vectors, can be introduced to the waveguide. However, these conventional excitation schemes are not convenient since this would require placing the excitation elements in the internal volume of the RF probe. A more efficient way is to apply (or collect) a signal between the waveguide and the conductive wire, e.g. between the waveguide and the conductive ring as illustrated in FIGS. 5a-c, where coaxial cables are used. In FIG. 5a four coaxial cables are used, each pair of coaxial cables excites one linear field. Introducing 90 deg. shift to the excitation, as illustrated in FIG. 5a, results in a circularly rotating magnetic field. This, in one embodiment of the invention the RF probe is configured for connection with at least one signal source for connection to a magnetic resonance system, said signal source applied between the waveguide and said first or second conductive wire.

The presently disclosed RF probe can potentially offer the following advantages over the prior art:
1. Reduced health risk due to potentially reduced SAR
2. Improved MR image quality because of potential increased homogeneity of the RF field
3. Reduced development, fabrication and operation costs due to potentially less design complexity

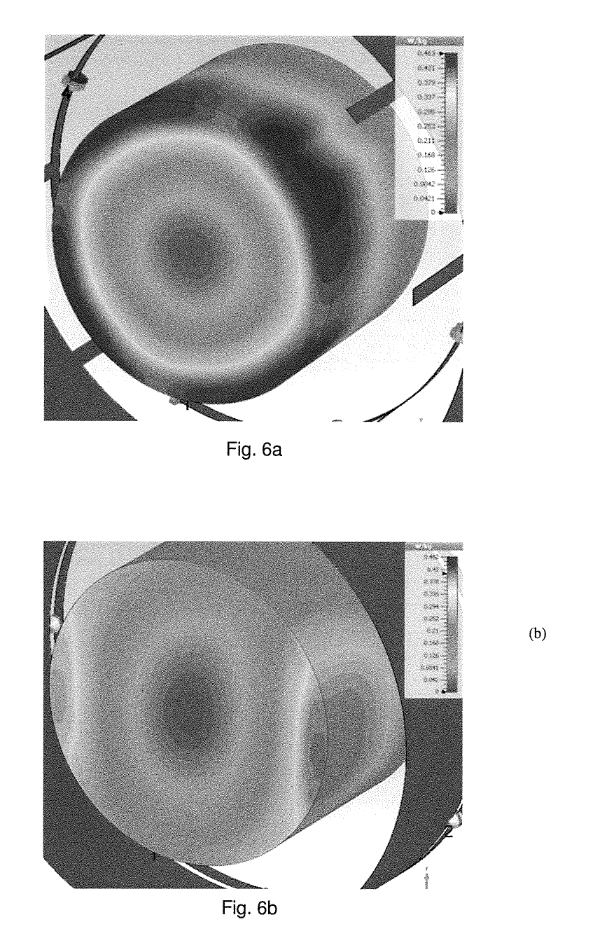

The health risk in MRI is quantified by the Specific Absorption Rate (SAR) values; the lower the SAR the smaller the health risk. FIGS. 6a and 6b compare SAR for a brain phantom for a conventional birdcage probe (FIG. 6a) and one embodiment of the present RF probe (FIG. 6b). As seen in FIG. 6a the maximum SAR for the birdcage probe is distributed along the circumference of the phantom, while the SAR distribution for the present RF probe (FIG. 6b) contains only two maxima with slightly lower amplitude. A simple cylindrical phantom with properties of brain tissue is used in FIG. 6.

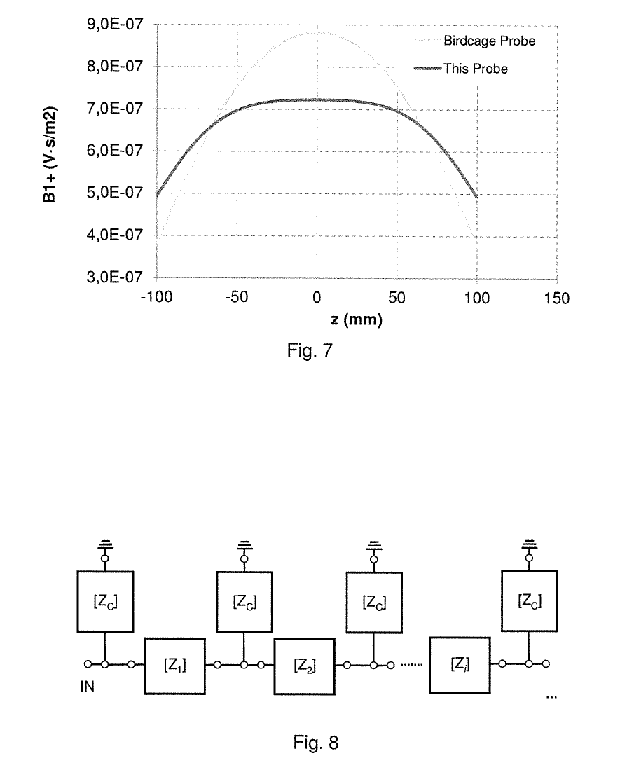

MR image quality depends on homogeneity of the field. The estimated homogeneity of the field (defined as a ratio between minimum and maximum of the field) for the present RF probe in the z direction is over 61% in comparison to 43% for the traditional birdcage probe as illustrated in FIG. 7. The compared homogeneity in the z direction is illustrated in FIG. 7 showing the amplitude of the magnetic field along the z-axis. Ideally, the line should be flat, but as seen from FIG. 7 presently disclosed RF probe at least can provide a more homogeneous field distribution compared to the prior art. It should however be noted that the homogeneity of the fields in x direction is 69% in comparison to 85% for the traditional Birdcage probe.

The presently disclosed RF probe requires much less circuit components compared to e.g. the birdcage probe. This is an important economical aspect since MR compliant components are often costly.

Prior to MR imaging a fine tuning for optimal operation is often required for an RF probe with the subject/sample inside the probe. It is found that with the presently disclosed probe this fine tuning is easier than the traditional birdcage probe. This can save a considerable amount of operation time during the preparations to the scanning procedure and it can also reduce the required time for a patient to be inside the scanner.

It is furthermore noted that the models for the traditional birdcage probes are comparatively complicated. The presently disclosed RF probe allows for more simplified and robust analysis which can significantly reduce the development time and cost.

The cutoff frequency fc of a circular waveguide can be calculated as

$${f}_{c} = \frac{1.841 c}{2 π a \sqrt{{ɛ}_{r}}}$$

where c is a speed of light, a is the radius of the waveguide, ∈ᵣ is the relative permittivity of the waveguide filling (1 for air).

Waveguides behave inductively below cutoff. The capacitance of the RF probe can therefore be chosen such that the structure resonates at a desired frequency f₀ using Thomson formula:

$$C = \frac{1}{{( 2 π {f}_{0} )}^{2} L} ,$$

where L is the equivalent inductance of the waveguide.

Below cutoff waveguide analysis can be conveniently formulated in terms of conventional network concepts. This formulation can then be used for analytical modeling of the structure. In the following analysis, currents and voltages are employed as measures of the fields within the below cutoff structure. The network analysis may be effected on an impedance basis.

Symmetric RF probes with two open ends can be used to construct probes with longer length by cascading several identical RF probes, i.e. connecting them in series as illustrated in FIG. 8 forming a network of RF probes. Each two-port network can be described by an impedance matrix. The waveguide section is described by [Zᵢ]. Capacitive elements are described by impedance matrices [Z_{C}].

The impedance matrix for the section of a below cutoff waveguide, [Zᵢ], is given by (cf. Pozar: “Microwave Engineering”, Wiley; 4^{th} ed.):

$$[ {Z}_{i} ] = [ \begin{matrix}{Z}_{0 ( W )} coth ( {γ}_{W} {l}_{i} ) & {Z}_{0 ( W )} csch ( {γ}_{W} {l}_{i} ) \\ {Z}_{0 ( W )} csch ( {γ}_{W} {l}_{i} ) & {Z}_{0 ( W )} coth ( {γ}_{W} {l}_{i} )\end{matrix} ] \qquad ( 1 )$$

Here Z_{0(w)} is the characteristic impedance, γ_{w} is the propagation constant, and lᵢ is the length of the corresponding waveguide section i, with i=1, 2, 3, . . . .

In order to apply transmission line theory to waveguides, the propagation constant and characteristic impedance of the particular guide configuration should be determined, as can be seen from the equation above.

The propagation constant of the circular waveguide is γ_{w}=α+jβₙₘ where

$$j {β}_{n m} = j ( 2 π f ) \sqrt{μ ɛ} \sqrt{1 - {( \frac{{f}_{{c}_{n m}}}{f} )}^{2}}$$

The cutoff frequency can be determined as

$${f}_{{c}_{n m}} = {f}_{{c}_{11}} = \frac{0.293}{a \sqrt{μ ɛ}}$$

where α is the radius of the waveguide.
The attenuation constant is α=α_{d}+α_{c}.

Attenuation due to the material filling the waveguide (subject to image) can be calculated as

$${α}_{d} = \frac{{k}^{2} tan δ}{2 β} Np \text{/} m ( TE or TM waves )$$

Attenuation due to conductor loss in waveguide can be calculated as

$${α}_{c} = \frac{{R}_{s}}{ak η β } ( {k}_{c}^{2} + \frac{{k}^{2}}{{p}_{11}^{′ 2} - 1} ) ,$$

where k=ω\sqrt{μ∈} is the wave number, and

$${k}_{c} = \frac{{p}_{n m}^{′}}{a}$$

is the cutoff wave number. p′ₙₘ=1.841.

The intrinsic impedance of the material filling the waveguide can be calculated as η=\sqrt{μ/∈}.

The surface resistance of the metal can be calculated as

$${R}_{s} = \sqrt{\frac{ω {μ}_{0}}{2 σ}}$$

where σ is the conductivity of the employed metal. The value for copper is 5.8e7 S/m. It has been found that the most accurate results are achieved using power-voltage definition for the characteristic impedance of the waveguide.

The matrix for the capacitive elements [Z_{C}] is defined by the impedance of the capacitor, simply 1/jωC, where C is the value of the capacitors. Using the model described above, the parameters of the present RF probe (diameter, length, and capacitance values) can be found iteratively.

### Examples

One exemplary RF probe is shown in FIG. 5a where the waveguide 1 is formed by a cylindrical section of copper mounted on a dielectric support tube with copper rings 3 forming the conducting wires mounted in axial extension of each end of the waveguide. Four capacitors 2 at each end of the waveguide connect the metallic rings 3 with the ends of the waveguide. The capacitors 2 ensure below cut-off operation of the waveguide 1. The connections between the waveguide and the four capacitors 2 at each end are distributed evenly around the rim of the waveguide, i.e. separated by approx. 90 degrees.

The RF probe can be connected to an MR system with a cable. A standard coaxial cable 4 is used in this realization refer to FIG. 5a for feeding the signal from the MR system. The signal is advantageously applied between the waveguide 1 and the ring 3 from a different position than the capacitor 2. In the case of a cylindrical waveguide as in FIG. 5a an angle of approximately 30° is found to be optimal for standard operation.

The presently disclosed RF probe may be configured to provide both linear and circularly polarized fields. Both polarizations are typically used in MR but circular polarization allows for better sensitivity than the linear polarization. One or two signal sources (i.e. cables) are required for linear field, as it is shown in FIG. 5b. Two, four or more signal sources are required for circular field, as it is illustrated in FIG. 5a with four signal sources. The higher the number of signal sources, the better the field homogeneity, which contributes to the MR image quality.

Two RF probe prototypes for different volumes have been fabricated as shown in FIG. 5c. Testing of electrical parameters was conducted in a microwave measurement laboratory. FIG. 5d shows the measured and predicted resonance frequency demonstrating only a small discrepancy. This validates the used probe model and confirms that the parameters of the probe can be accurately predicted using full-wave analysis.

1. An RF probe for magnetic resonance imaging and/or spectroscopy, comprising:
a conductive non-magnetic hollow waveguide comprising a pipe or tube formed by one closed cylindrical surface, said waveguide having an internal volume and at least one open end;
one or more capacitors; and
at least a first conductive non-magnetic wire;
wherein said first conductive wire connects at least one of said one or more capacitors to opposite walls of one of the at least one open end of the waveguide and wherein said first conductive wire and said one or more capacitors are located outside of said internal volume; and
wherein the internal volume of the hollow waveguide defines an imaging volume or sample volume.

2. The RF probe according to claim 1, wherein the at least one open end of the hollow waveguide comprises two open ends.

3. The RF probe according to claim 1, wherein said one or more capacitors are selected such that the resonance frequency of the RF probe is below a cutoff frequency of the hollow waveguide.

4. The RF probe according to claim 1, wherein:
said one or more capacitors comprises at least two capacitors connected in series; and
said first conductive wire connects two of said at least two capacitors to opposite walls of one of the at least one open end of the waveguide.

5. The RF probe according to claim 1, wherein:
said one or more capacitors comprises at least four capacitors; and
said first conductive wire connects four of said at least four capacitors to one of the at least one open end of the waveguide, said four capacitor connections distributed evenly around a rim of said one open end of the waveguide.

6. The RF probe according to claim 1, wherein:
said one or more capacitors comprises at least two capacitors; and
the RF probe further comprises at least a second conductive non-magnetic wire, wherein the second wire connects at least one of said at least two capacitors to opposite walls of an end of the waveguide opposite the at least one open end.

7. The RF probe according claim 6, wherein:
said one or more capacitors comprises at least four capacitors; and
said second conductive wire connects two of said at least four capacitors to opposite walls of said opposite end of the waveguide.

8. The RF probe according to claim 6, wherein:
said one or more capacitors comprises at least eight capacitors; and
said second conductive wire connects four of said at least eight capacitors to the opposite end of the waveguide, said four capacitor connections distributed evenly around a rim of said opposite end of the waveguide.

9. The RF probe according to claim 1, wherein the first conductive non-magnetic wire extends in an axial extension of the waveguide.

10. The RF probe according to claim 1, wherein the first conductive non-magnetic wire forms a closed loop.

11. The RF probe according to claim 1, wherein the first conductive non-magnetic wire forms an elliptical ring.

12. The RF probe according to claim 1, wherein the hollow waveguide is straight and/or elongated.

13. The RF probe according to claim 1, wherein the hollow waveguide is rectangular.

14. The RF probe according to claim 1, wherein a cross-section of the hollow waveguide is elliptical.

15. The RF probe according to claim 1, wherein a cross-section of the hollow waveguide forms a polygon selected from a group consisting of a equilateral and/or convex polygon, a polygon, a triangle, a square, a pentagon, a hexagon, and a heptagon.

16. The RF probe according to claim 1, wherein the RF probe is configured to operate below a cut-off frequency of the hollow waveguide.

17. The RF probe according to claim 1, wherein the hollow waveguide and/or the first conductive wire are manufactured of a non-magnetic metal.

18. The RF probe according to claim 1, wherein the waveguide and/or the first conductive wire are mounted on a dielectric support structure.

19. The RF probe according to claim 1, wherein the surface of the waveguide is at least partly solid.

20. The RF probe according to claim 1, wherein the surface of the waveguide is at least partly meshed.

21. The RF probe according to claim 1, wherein the hollow waveguide is a self-supporting structure.

22. The RF probe according to claim 1, wherein the RF probe is configured for connection with at least one signal source for connection to a magnetic resonance system, said signal source applied between the waveguide and said first conductive wire.
